(19) United States
(12) Patent Application Publication
(10) Pub. No.: US 2022/0051974 A1
(43) Pub. Date: Feb. 17, 2022

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventor: Lei WANG, Hefei (CN)

(21) Appl. No.: 17/409,876

(22) Filed: Aug. 24, 2021

Related U.S. Application Data
(63) Continuation of application No. PCT/CN2021/094441, filed on May 18, 2021.

(30) Foreign Application Priority Data
Aug. 13, 2020 (CN) 202010811914.1

(51) Int. Cl. H01L 23/522; H01L 23/532; H01L 21/768

(52) U.S. Cl. CPC H01L 23/5226; H01L 23/53238; H01L 23/53223; H01L 21/76877; H01L 21/76802; H01L 21/76843; H01L 23/53266

(57) ABSTRACT

Provided are a semiconductor structure and a method for manufacturing a semiconductor structure. The semiconductor structure includes a semiconductor base, a diffusion barrier layer, and a conductive plug. The semiconductor base is provided with a plug contact hole. A bottom of a sidewall of the plug contact hole is provided with a groove. The diffusion barrier layer is arranged on a wall of the plug contact hole and fills the groove. The conductive plug is arranged on the diffusion barrier layer.

### CROSS-REFERENCE TO RELATED APPLICATIONS

This is a continuation application of International Patent Application No. PCT/CN2021/094441, filed on May 18, 2021, which claims priority to Chinese Patent Application No. 202010811914.1, filed on Aug. 13, 2020 and entitled “SEMICONDUCTOR STRUCTURE AND METHOD FOR MANUFACTURING SEMICONDUCTOR STRUCTURE”. The disclosures of International Patent Application No. PCT/CN2021/094441 and Chinese Patent Application No. 202010811914.1 are hereby incorporated by reference in their entireties.

### TECHNICAL FIELD

The present disclosure relates to the technical field of semiconductors, and particularly to a semiconductor structure and a method for manufacturing the semiconductor structure.

### BACKGROUND

With the increasing integration level of semiconductors, a size of a circuit becomes smaller, a depth a conductive plug contact structure can reach becomes deeper and a current density becomes greater. A current is likely to be leaked when the conductive plug contact structure is subjected to the high-density current, thus the performance of the semiconductor may be reduced.

### SUMMARY

The present disclosure provides a semiconductor structure and a method for manufacturing the semiconductor structure, to improve the performance of the semiconductor structure.

According to a first aspect of the disclosure, there is provided a semiconductor structure, the semiconductor structure includes a semiconductor base, a diffusion barrier layer, and a conductive plug.

The semiconductor base is provided with a plug contact hole, and a groove is provided at a bottom portion of a sidewall of the plug contact hole.

The diffusion barrier layer is arranged on a hole wall of the plug contact hole and fills the groove.

The conductive plug is arranged on the diffusion barrier layer.

According to a second aspect of the disclosure, there is provided a method for manufacturing a semiconductor structure, the method includes the following operations.

A semiconductor base with a plug contact hole is formed. A groove is provided at a bottom portion of a sidewall of the plug contact hole and filled with a first diffusion barrier material.

A second diffusion barrier material is formed on the semiconductor base. The second diffusion barrier material covers an inner wall of the first diffusion barrier material and a hole wall of the plug contact hole. The first diffusion barrier material and the second diffusion barrier material form a diffusion barrier layer.

The plug contact hole within the diffusion barrier layer is filled to form a conductive plug.

According to a third aspect of the disclosure, there is provided a method for manufacturing a semiconductor structure, the method includes the following operations.

A semiconductor base with a plug contact hole is formed. A groove is provided at a bottom portion of a sidewall of the plug contact hole.

A diffusion barrier layer is formed on the semiconductor base. The diffusion barrier layer is arranged on a hole wall of the plug contact hole and fills the groove.

The plug contact hole within the diffusion barrier layer is filled to form a conductive plug.

### BRIEF DESCRIPTION OF THE DRAWINGS

Various objects, features, and advantages of the disclosure will become more apparent from the following detailed description of preferred embodiments of the disclosure when considered in combination with the accompanying drawings. The drawings are merely exemplary illustrations of the disclosure and are not necessarily drawn to scale. In the drawings, like reference numerals refer to the same or similar parts throughout.

FIG. 1 is a structure diagram illustrating a semiconductor structure according to an exemplary embodiment.

FIG. 2 is a flow chart illustrating a method for manufacturing a semiconductor structure according to an exemplary embodiment.

FIG. 3 is a structure diagram illustrating a dielectric material being formed on a substrate in a method for manufacturing a semiconductor structure according to an exemplary embodiment.

FIG. 4 is a structure diagram illustrating a dielectric layer being formed on a substrate in a method for manufacturing a semiconductor structure according to an exemplary embodiment.

FIG. 5 is a structure diagram illustrating a first diffusion barrier material being formed in a method for manufacturing a semiconductor structure according to an exemplary embodiment.

FIG. 6 is a structure diagram illustrating a first diffusion barrier material being partially removed in a method for manufacturing a semiconductor structure according to an exemplary embodiment.

FIG. 7 is a structure diagram illustrating an opening being formed in a method for manufacturing a semiconductor structure according to an exemplary embodiment.

FIG. 8 is a structure diagram illustrating a protective material being formed in a method for manufacturing a semiconductor structure according to an exemplary embodiment.

FIG. 9 is a structure diagram illustrating a protective layer being formed in a method for manufacturing a semiconductor structure according to an exemplary embodiment.

FIG. 10 is a structure diagram illustrating a diffusion barrier layer being formed in a method for manufacturing a semiconductor structure according to an exemplary embodiment.

FIG. 11 is a flow chart illustrating a method for manufacturing a semiconductor structure according to another exemplary embodiment.

Elements with reference numerals are illustrated as follows.

A semiconductor base 10, a substrate 11, a dielectric layer 12, a first via 121, a protective layer 13, a second via 131, a plug contact hole 14, a groove 15, a diffusion barrier layer 20, a first main portion 21, a first protrusion portion 22, a conductive plug 30, a second main portion 31, a second protrusion portion 32, a first diffusion barrier material 40, an opening 41, a dielectric material 42, a protective material 43, and a second diffusion barrier material 44.

### DETAILED DESCRIPTION

Typical embodiments that embody the features and advantages of the disclosure will be described in detail in the following description. It should be understood that the disclosure have changes in different embodiments without departing from the scope of the disclosure, and that the description and drawings are illustrative in nature and are not intended to limit the disclosure.

The following description of different exemplary embodiments of the disclosure is described with reference to the accompanying drawings, which form a part of the disclosure, and in which different exemplary structures, systems, and operations for implementing various aspects of the disclosure are shown by way of examples. It should be understood that other specific solutions of parts, structures, exemplary devices, systems, and operations may be utilized, and structural and functional modifications may be made without departing from the scope of the disclosure. Moreover, terms such as “above”, “between”, “within” may be used in the specification to describe different exemplary features and elements of the disclosure, these terms used herein are for convenience only, for example, according to a direction of the examples in the drawings. Any content in the specification should not be construed as requiring a particular three-dimensional direction of the structure to fall within the scope of the disclosure.

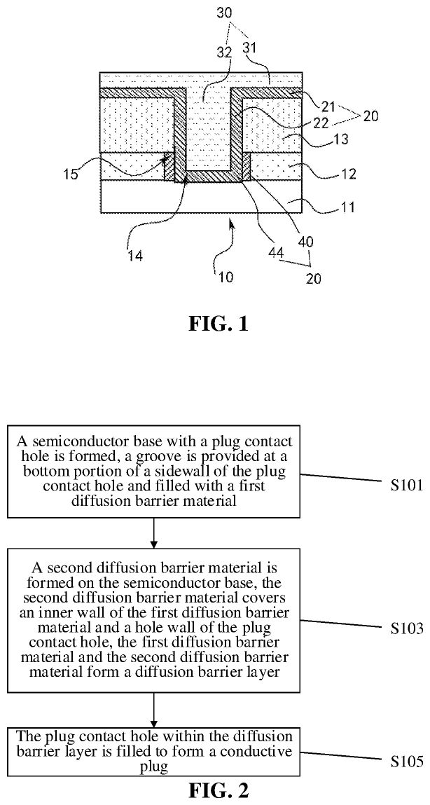

An embodiment of the disclosure provides a semiconductor structure. Referring to FIG. 1, the semiconductor structure includes a semiconductor base 10, a diffusion barrier layer 20 and a conductive plug 30. The semiconductor base 10 is provided with a plug contact hole 14, and a groove 15 is provided at a bottom portion of a sidewall of the plug contact hole 14. The diffusion barrier layer is arranged on a hole wall of the plug contact hole 14 and fills the groove 15. The conductive plug 30 is arranged on the diffusion barrier layer 20.

In the semiconductor structure according to an embodiment of the disclosure, the diffusion barrier layer 20 is embedded in the semiconductor base 10, and the contact area between the diffusion barrier layer 20 and the semiconductor base 10 is increased, such that the current leakage can be reduced, and the stability of the semiconductor structure can be improved.

Specifically, the semiconductor base 10 is provided with the plug contact hole 14, it can be understood that the semiconductor base 10 has an accommodating groove. The plug contact hole 14 has an opening, and the groove 15 is arranged around the hole wall of the plug contact hole 14 along a circumferential direction of the plug contact hole 14, that is, an annular groove is formed in the hole wall of the plug contact hole 14, the annular groove is an embedded groove with respect to the plug contact hole 14.

The diffusion barrier layer 20 is arranged on the hole wall of the plug contact hole 14, that is, the diffusion barrier layer 20 is also arranged outside the opening of the groove 15, rather than only arranged in the groove 15. In such way, the diffusion barrier layer 20 between a bottom of a sidewall of the conductive plug 30 and the semiconductor base 10 is relatively thick.

In an embodiment, the conductive plug 30 may be a metal material such as Cu, Al, W, or alloys thereof.

In an embodiment, the diffusion barrier layer 20 may include, for example, Ta, Ti, Ru, TaN, TiN, RuTa, RuTaN, W or Ir. The diffusion barrier layer 20 may also be any other material that can prevent the conductive material from diffusion and passing.

In an embodiment, the semiconductor base 10 includes a substrate 11, a dielectric layer 12 and a protective layer 13. The dielectric layer 12 is arranged on the substrate 11, and the dielectric layer 12 is provided with a first via 121. The protective layer 13 is arranged on the dielectric layer 12, and the protective layer 13 is provided with a second via 131. The first via 121 is communicated with the second via 131, and a vertical projection of the second via 131 towards the substrate 11 is within a vertical projection of the first via 121 towards the substrate 11. The groove 15 is formed between the substrate 11 and the protective layer 13.

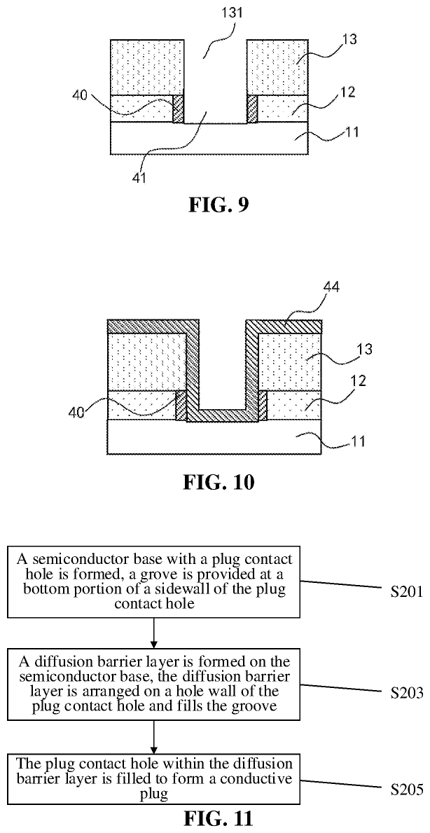

Specifically, the description will be described with reference to FIG. 4 and FIG. 9. The dielectric layer 12 is arranged on substrate 11, the first via 121 is defined in a center of the dielectric layer 12, in such way, an upper surface of the substrate 11 is exposed. Moreover, the protective layer 13 is arranged on the dielectric layer 12, and the second via 131 is defined in a center of the protective layer 13. A portion of the first via 121 may be exposed since an aperture of the second via 131 is smaller than an aperture of the first via 121. Therefore, another portion of the first via 121 may be covered by the protective layer 13, and the groove 15 is formed by the covered space between the substrate 11 and the protective layer 13 (referring to FIG. 9, the groove 15 is filled with a first diffusion barrier material 40).

In an embodiment, the substrate 11 may include a semiconductor substrate. The semiconductor substrate may be formed of a silicon-containing material. The semiconductor substrate may be formed of a suitable material including, for example, at least one of: silicon, monocrystalline silicon, polycrystalline silicon, amorphous silicon, silicon germanium, monocrystalline silicon germanium, polycrystalline silicon germanium, or carbon-doped silicon.

In an embodiment, the dielectric layer 12 may include a material such as SiN or SiCN.

In an embodiment, protective layer 13 may include a material such as SiO2 or SiOC.

In an embodiment, the groove 15 has a depth of 5 nm-20 nm in a first direction. and the first direction is perpendicular to an extension direction of the first via 121. On the basis of a thickness of the diffusion barrier layer 20 covering the hole wall of the plug contact hole 14, the diffusion barrier layer 20 with a thickness of 5 nm-20 nm is added, such that the thickness of the diffusion barrier layer 20 on the bottom of the sidewall of the conductive plug 30 is increased, and the metal material which forms the conductive plug 30 can be prevented from diffusion.

It is noted that the extension direction of the first via 121 is the direction perpendicular to the substrate 11, thus, it can be understood that the first direction is parallel to the substrate 11. Correspondingly, the second direction is perpendicular to the substrate 11, and therefore the first direction is perpendicular to the second direction. Being perpendicular to the substrate 11 may be understood as being perpendicular to the upper surface of the substrate 11.

It is noted that the groove 15 may be filled with the diffusion barrier layer 20.

In an embodiment, the dielectric layer 12 has a thickness of 20 nm-200 nm in the second direction.

In an embodiment, the protective layer 13 has a thickness of 50 nm-500 nm in the second direction.

In an embodiment, as illustrated in FIG. 1, the diffusion barrier layer 20 is arranged between the semiconductor base 10 and the conductive plug 30, that is, the semiconductor base 10 and the conductive plug 30 are completely separated by the diffusion barrier layer 20.

In an embodiment, the diffusion barrier layer 20 includes a first main portion 21 and a first protrusion portion 22. The first protrusion portion 22 is arranged on the hole wall of the plug contact hole 14 and fills the groove 15. The first main portion 21 is arranged on the semiconductor base 10 and outside the plug contact hole 14. The conductive plug 30 includes a second main portion 31 and a second protrusion portion 32. The second protrusion portion 32 is arranged inside the first main portion 21 and the first protrusion portion 22. The second main portion 31 is arranged on the first main portion 21.

Specifically, the description will be described with reference to FIG. 1. The first protrusion portion 22 of the diffusion barrier layer 20 is arranged inside the semiconductor base 10, that is, arranged on the hole wall of the plug contact hole 14 and in the groove 15. The first main portion 21 of the diffusion barrier layer 20 covers the upper surface of the semiconductor base 10. Correspondingly, the second protrusion portion 32 of the conductive plug 30 fills accommodating space formed by the first main portion 21 and the first protrusion portion 22. The second main portion 31 of the conductive plug 30 covers the upper surface of the diffusion barrier layer 20, that is, the semiconductor base 10 and the conductive plug 30 are completely separated by the diffusion barrier layer 20.

In an embodiment, the first main portion 21 has a thickness of 10 nm-50 nm in the second direction.

In an embodiment, the second main portion 31 has a thickness of 100 nm-800 nm in the second direction.

In an embodiment, as illustrated in FIG. 1, the diffusion barrier layer 20 includes a first diffusion barrier material 40 and a second diffusion barrier material 44. The first diffusion barrier material 40 fills the groove 15, and the second diffusion barrier material 44 covers an inner wall of the first diffusion barrier material 40 and an inner wall of the protective layer 13.

Specifically, the first diffusion barrier material 40 and the second diffusion barrier material 44 may be formed integrally, that is, integrally formed in the groove 15 and the plug contact hole 14. Alternatively, the first diffusion barrier material 40 and the second diffusion barrier material 44 may be formed separately, that is, the first diffusion barrier material 40 fills the groove 15, and then after some steps, the second diffusion barrier material 44 is formed in the plug contact hole 14.

The description will be described with reference to FIG. 1. The diffusion barrier layer 20 includes the first diffusion barrier material 40 and the second diffusion barrier material 44. The first main portion 21 of the diffusion barrier layer 20 includes some of the second diffusion barrier material 44 which covers the upper surface of the semiconductor base 10. The first protrusion portion 22 of the diffusion barrier layer 20 includes some of the second diffusion barrier material 44 and the entire first diffusion barrier material 40.

In the semiconductor structure according to the disclosure, some of the diffusion barrier layer 20 is embedded in the semiconductor base 10, to withstand metal stress generated by the conductive plug 30, and further to resist impact of the high-density current. Moreover, a contact area between the diffusion barrier layer and the semiconductor base is increased, such that the current leakage can be reduced. Therefore, the stability of the semiconductor structure can be improved.

An embodiment of the disclosure also provides a method for manufacturing a semiconductor structure, referring to FIG. 2, the method includes the following operations.

At S101, a semiconductor base 10 with a plug contact hole 14 is formed. A groove 15 is provided at a bottom portion of a sidewall of the plug contact hole 14 and filled with a first diffusion barrier material 40.

At S103, a second diffusion barrier material 44 is formed on the semiconductor base 10. The second diffusion barrier material 44 covers an inner wall of the first diffusion barrier material 40 and a hole wall of the plug contact hole 14. The first diffusion barrier material 40 and the second diffusion barrier material 44 form a diffusion barrier layer 20.

At S105, the plug contact hole 14 within the diffusion barrier layer 20 is filled to form a conductive plug 30.

In the method for manufacturing the semiconductor structure according to the embodiment of the disclosure, the groove 15 of the semiconductor base 10 is filled with the diffusion barrier layer 20 to form the embedded diffusion barrier layer 20, and the contact area between the diffusion barrier layer 20 and the semiconductor base 10 is increased, such that the current leakage can be reduced, and the stability of the semiconductor structure can be improved.

It is noted that the groove 15 is filled with the first diffusion barrier material 40, the plug contact hole 14 is filled with the second diffusion barrier material 44, in such way, the first diffusion barrier material 40 and the second diffusion barrier material 44 form the diffusion barrier layer 20.

In an embodiment, the operation that the semiconductor base 10 with the plug contact hole 14 is formed includes the following actions. A substrate 11 is provided. A dielectric layer 12 with a first via 121 is formed on the substrate 11. The first diffusion barrier material 40 fills the first via 121 and covers the dielectric layer 12. The first diffusion barrier material 40 on the dielectric layer 12 is removed to expose the dielectric layer 12, and an upper surface of a remaining first diffusion barrier material 40 is flush with an upper surface of the dielectric layer 12. The first diffusion barrier material 40 in the first via 121 is partially etched to form an opening 41 in the first diffusion barrier material 40 and expose the substrate 11. A protective layer 13 with a second via 131 is formed on the dielectric layer 12, the second via 131 is communicated with the opening 41, and an orifice of the second via 131 coincides with an orifice of the opening 41.

In an embodiment, the operation that the semiconductor base 10 is formed includes that the following actions. A substrate 11 is provided. A dielectric layer 12 with a first via 121 is formed on the substrate 11. The protective layer 13 with a second via 131 is formed on the dielectric layer 12, and the first via 121 is communicated with the second via 131. The groove 15 is formed between the substrate 11 and the protective layer 13.

The semiconductor base 10 may include the substrate 11, the dielectric layer 12, and the protective layer 13. The dielectric layer 12 and the protective layer 13 are sequentially formed on the substrate 11, in other words, after the dielectric layer 12 is formed on the substrate 11, the protective layer 13 is formed on the dielectric layer 12.

It is noted that the substrate 11 may be selected from silicon-containing semiconductor substrates. The semiconductor substrate may be formed of a suitable material including, for example, at least one of: silicon, monocrystalline silicon, polycrystalline silicon, amorphous silicon, silicon germanium, monocrystalline silicon germanium, polycrystalline silicon germanium, or carbon-doped silicon.

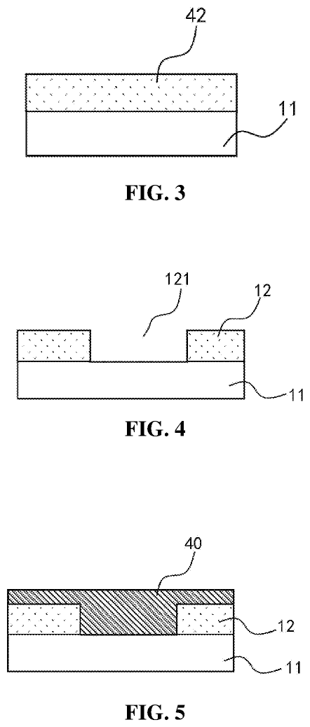

In an embodiment, as illustrated in FIG. 3, after the dielectric material 42 covers the substrate 11, the dielectric material 42 is etched to form the first via 121 on the dielectric material 42 and expose the upper surface of the substrate 11, as illustrated in FIG. 4, in such way, the dielectric layer 12 with the first via 121 is formed on the substrate 11.

Specifically, the dielectric material 42 may include a material such as SiN or SiCN. The dielectric material 42 may be arranged on the substrate 11 by using a process such as Physical Vapor Deposition (PVD), Chemical Vapor Deposition (CVD), or Atomic Layer Deposition (ALD). Then, the dielectric material 42 may be dry-etched or wet-etched to form the first via 121. The dielectric layer 12 has a thickness of 20 nm-200 nm.

In an embodiment, before the protective layer 13 is formed, the first diffusion barrier material 40 fills the first via 121 and covers the dielectric layer 12. After the first via 121 is formed, the first diffusion barrier material 40 fills the first via 121, and then most of the first diffusion barrier material 40 is removed, and a small amount of the first diffusion barrier material 40 filling the first via 121 is reserved and used for filling the groove 15. Therefore, a portion of the diffusion barrier layer 20 embedded in the semiconductor base 10 is formed.

Specifically, the first diffusion barrier material 40 may include, for example, Ta, Ti, Ru, TaN, TiN, RuTa, RuTaN, W or Ir. The first diffusion barrier material 40 may also be any other material that can prevent the conductive material from diffusion and passing.

On the basis of FIG. 4, the first diffusion barrier material 40 may be formed on the dielectric layer 12 by using a process such as PVD, CVD, or ALD. As illustrated in FIG. 5, the first diffusion barrier material 40 fills the first via 121 and covers the dielectric layer 12.

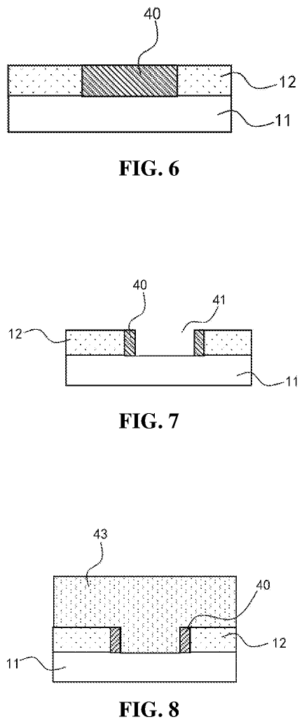

The first diffusion barrier material 40 covering the dielectric layer 12 is removed by using dry etching or Chemical Mechanical Polishing (CMP), to expose the dielectric layer 12, as illustrated in FIG. 6, the dielectric layer 12 is flush with the first diffusion barrier material 40 in the first via 121.

Then, as illustrated in FIG. 7, the first diffusion barrier material 40 in the first via 121 is dry-etched to form the opening 41 in the first diffusion barrier material 40 and expose the substrate 11. The thickness of the first diffusion barrier material 40 finally remained is 5 nm-20 nm, that is, the groove 15 in the first direction has the depth of 5 nm-20 nm.

In an embodiment, the operation that the protective layer 13 is formed includes the following actions. A protective material 43 fills the opening 41 and covers the dielectric layer 12 and the first diffusion barrier material 40. The protective material 43 is etched to form the protective layer 13 with the second via 131 from the protective material 43, and the opening 41 is formed by etching.

Specifically, the protective material 43 may include a material such as SiO2 or SiOC.

On the basis of FIG. 7, the protective material 43 may be formed on the dielectric layer 12 and the first diffusion barrier material 40 by using a process such as PVD, CVD, or ALD, and as illustrated in FIG. 8, the protective material 43 fills the opening 41.

The protective material 43 is dry-etched along a direction the opening 41 towards, to completely remove the protective material 43 in the direction the opening 41 towards and expose the complete opening 41, thus the protective layer 13 with the second via 131 is formed. As illustrated in FIG. 9, an aperture of the second via 131 is equal to an aperture of the opening 41, that is, a cross-sectional area of the second via 131 is equal to a cross-sectional area of the opening 41. The thickness of the protective material 43 on the dielectric layer 12 and the first diffusion barrier material 40 is 50 nm-500 nm, that is, the protective layer 13 has the thickness of 50 nm-500 nm.

Specifically, a ratio of the thickness of the dielectric layer 12 in the second direction to the thickness of the protective layer 13 in the second direction may be 5%-30%, such as 8%, 10%, 15% or 20%. Accordingly, in the semiconductor structure finally formed, the ratio of the height of the groove 15 in the second direction to the height of the plug contact hole in the second direction may be 5%-30%.

In an embodiment, after the protective layer 13 is formed, the method for manufacturing the semiconductor structure further includes the following operations. The second diffusion barrier material 44 covers a hole wall of the opening 41, a hole wall of the second via 131 and the protective layer 13. The first diffusion barrier material 40 and the second diffusion barrier material 44 form the diffusion barrier layer 20.

Specifically, the second diffusion barrier material 44 may include, for example, Ta, Ti, Ru, TaN, TiN, RuTa, RuTaN, W or Ir. The second diffusion barrier material 44 may also be any other material that can prevent the conductive material from diffusion and passing. The first diffusion barrier material 40 and the second diffusion barrier material 44 may include the same material, and they may also include different materials.

On the basis of FIG. 9, the second diffusion barrier material 44 may be formed on the hole wall of the opening 41, the hole wall of the second via 131, and the upper surface of the protective layer 13 by using a process such as PVD, CVD, or ALD, as illustrated in FIG. 10. The thickness of the second diffusion barrier material 44 which covers the protective layer 13 is 10 nm-50 nm, the first diffusion barrier material 40 in the groove 15 and the second diffusion barrier material 44 form the diffusion barrier layer 20. In summary, the diffusion barrier layer 20 is prepared in two steps.

Finally, Cu, Al, W or alloys thereof may fill the plug contact hole within the second diffusion barrier material 44 and cover the upper surface of the second diffusion barrier material 44 by using a process such as PVD, CVD, or ALD, to form the conductive plug 30, so as to implement the manufacturing of the semiconductor structure illustrated in FIG. 1. The thickness of the conductive plug 30 covering the upper surface of the second diffusion barrier material 44 is 100 nm-800 nm.

In an embodiment, the method for manufacturing the semiconductor structure is used for manufacturing the above semiconductor structure.

In the method for manufacturing the semiconductor structure according to the disclosure, the semiconductor base 10 is sequentially filled with the first diffusion barrier material 40 and the second diffusion barrier material 44, and the first diffusion barrier material 40 is embedded in the semiconductor base 10, to withstand the metal stress generated by the conductive plug 30, and further to resist the impact of the high-density current. Therefore, the stability of the semiconductor structure can be improved.

An embodiment of the disclosure also provides a method for manufacturing a semiconductor structure, referring to FIG. 11, the method includes the following operations.

At S201, a semiconductor base 10 with a plug contact hole 14 is formed. A groove 15 is provided at a bottom portion of a sidewall of the plug contact hole 14.

At S203, a diffusion barrier layer 20 is formed on the semiconductor base 10. The diffusion barrier layer 20 is arranged on a hole wall of the plug contact hole 14 and fills the groove 15.

At S205, the plug contact hole 14 within the diffusion barrier layer 20 is filled to form a conductive plug 30.

In the method for manufacturing the semiconductor structure according to the embodiment of the disclosure, the groove 15 of the semiconductor base 10 is filled with the diffusion barrier layer 20, the embedded diffusion barrier layer 20 is formed, and the contact area between the diffusion barrier layer 20 and the semiconductor base 10 is increased, such that the current leakage can be reduced, and the stability of the semiconductor structure can be improved.

It is noted that in the embodiment, the diffusion barrier layer 20 fills the groove 15 and the plug contact hole 14 at one time.

In an embodiment, the operation that the semiconductor base 10 is formed includes the following actions. A substrate 11 is provided. A dielectric layer 12 with a first via 121 is formed on the substrate 11. A protective layer 13 with a second via 131 is formed on the dielectric layer 12, the first via 121 is communicated with the second via 131, and a vertical projection of the second via 131 towards the substrate 11 is within a vertical projection of the first via 121 towards the substrate 11. The groove 15 is formed between the substrate 11 and the protective layer 13.

Specifically, the groove 15 and the plug contact hole 14 are obtained from two processes which include sequentially forming the first via 121 and the second via 131. After the first via 121 and the second via 131 are formed, the diffusion barrier layer 20 is filled at one time.

In an embodiment, the groove 15 and the plug contact hole 14 are formed in the semiconductor base 10 by etching in a manner of side etching or adjusting etching selectivity, and then the diffusion barrier layer 20 is formed in the groove 15 and the plug contact hole 14.

Specifically, the dielectric layer 12 and the protective layer 13 are sequentially formed on the substrate 11, then the protective layer 13 and the dielectric layer 12 are etched in the manner of side etching or adjusting the etching selection selectivity, to form a wider via in the dielectric layer 12, in such way, the groove 15 and the plug contact hole 14 are formed in the dielectric layer 12 and the protective layer 13.

In an embodiment, the method for manufacturing the semiconductor structure is used for manufacturing the above semiconductor structure.

According to the method for manufacturing the semiconductor structure of the disclosure, the semiconductor base 10 is filled with the diffusion barrier layer 20 at one time, and the diffusion barrier layer 20 is embedded in the semiconductor base 10, to withstand the metal stress generated by the conductive plug 30, and further to resist the impact of the high-density current. Therefore, the stability of the semiconductor structure can be improved.

Other embodiments of the disclosure will be apparent to those skilled in the art from consideration of the specification and practice of the disclosure disclosed herein. The disclosure is intended to cover any variations, uses, or adaptations of the disclosure, and the variations, uses, or adaptations of the disclosure following the general principles thereof and including such departures from the disclosure as come within known or customary practice in the art. The specification and embodiments are considered as exemplary only, with a true scope and spirit of the disclosure being indicated by the claims.

It will be appreciated that the disclosure is not limited to the exact construction that has been described above and illustrated in the accompanying drawings, and that various modifications and changes may be made without departing from the scope thereof. The scope of the disclosure is limited only by the appended claims.

1. A semiconductor structure, comprising:
a semiconductor base, the semiconductor base being provided with a plug contact hole, and a groove being provided at a bottom portion of a sidewall of the plug contact hole;
a diffusion barrier layer, the diffusion barrier layer being arranged on a hole wall of the plug contact hole and filling the groove; and
a conductive plug, the conductive plug being arranged on the diffusion barrier layer.

2. The semiconductor structure of claim 1, wherein the semiconductor base comprises:
a substrate;
a dielectric layer, the dielectric layer being arranged on the substrate and being provided with a first via; and
a protective layer, the protective layer being arranged on the dielectric layer and being provided with a second via, wherein the first via is communicated with the second via, and a vertical projection of the second via towards the substrate is within a vertical projection of the first via towards the substrate, and wherein
the groove is formed between the substrate and the protective layer.

3. The semiconductor structure of claim 2, wherein the groove has a depth of 5 nm-20 nm in a first direction, and the first direction is perpendicular to an extension direction of the first via.

4. The semiconductor structure of claim 3, wherein the dielectric layer has a thickness of 20 nm-200 nm in a second direction, the protective layer has a thickness of 50 nm-500 nm in the second direction, and the second direction is perpendicular to the substrate.

5. The semiconductor structure of claim 2, wherein the diffusion barrier layer is arranged between the semiconductor base and the conductive plug.

6. The semiconductor structure of claim 5, wherein the diffusion barrier layer comprises a first main portion and a first protrusion portion, the first protrusion portion is arranged on the hole wall of the plug contact hole and fills the groove, and the first main portion is arranged on the semiconductor base and outside the plug contact hole; and
the conductive plug comprises a second main portion and a second protrusion portion, the second protrusion portion is arranged inside the first main portion and the first protrusion portion, and the second main portion is arranged on the first main portion.

7. The semiconductor structure of claim 6, wherein the first main portion has a thickness of 10 nm-50 nm in a second direction, the second main portion has a thickness of 100 nm-800 nm in the second direction, and the second direction is perpendicular to the substrate.

8. The semiconductor structure of claim 2, wherein the diffusion barrier layer comprises a first diffusion barrier material and a second diffusion barrier material, the first diffusion barrier material fills the groove, and the second diffusion barrier material covers an inner wall of the first diffusion barrier material and an inner wall of the protective layer.

9. A method for manufacturing a semiconductor structure, comprising:
forming a semiconductor base with a plug contact hole, a groove being provided at a bottom portion of a sidewall of the plug contact hole and filled with a first diffusion barrier material;
forming a second diffusion barrier material on the semiconductor base, the second diffusion barrier material covering an inner wall of the first diffusion barrier material and a hole wall of the plug contact hole, the first diffusion barrier material and the second diffusion barrier material forming a diffusion barrier layer; and
filling the plug contact hole within the diffusion barrier layer to form a conductive plug.

10. The method for manufacturing the semiconductor structure of claim 9, wherein forming the semiconductor base with the plug contact hole comprises:
providing a substrate;
forming a dielectric layer with a first via on the substrate;
filling the first via and covering the dielectric layer with the first diffusion barrier material;
removing the first diffusion barrier material on the dielectric layer to expose the dielectric layer, wherein an upper surface of a remaining first diffusion barrier material is flush with an upper surface of the dielectric layer;
partially etching the first diffusion barrier material in the first via, to form an opening in the first diffusion barrier material and expose the substrate; and
forming a protective layer with a second via on the dielectric layer, wherein the second via is communicated with the opening, and an orifice of the second via coincides with an orifice of the opening.

11. The method for manufacturing the semiconductor structure of claim 10, wherein forming the protective layer comprises:
filling the opening and covering the dielectric layer and the first diffusion barrier material with a protective material; and
etching the protective material to form the protective layer with the second via from the protective material and form the opening.

12. The method for manufacturing the semiconductor structure of claim 10, wherein after forming the protective layer, the method for manufacturing the semiconductor structure further comprises:
covering a hole wall of the opening, a hole wall of the second via and the protective layer with the second diffusion barrier material.

13. A method for manufacturing a semiconductor structure, comprising:
forming a semiconductor base with a plug contact hole, a groove being provided at a bottom portion of a sidewall of the plug contact hole;
forming a diffusion barrier layer on the semiconductor base, the diffusion barrier layer being arranged on a hole wall of the plug contact hole and filling the groove; and
filling the plug contact hole within the diffusion barrier layer to form a conductive plug.

14. The method for manufacturing the semiconductor structure of claim 13, wherein forming the semiconductor base comprises:
providing a substrate;
forming a dielectric layer with a first via on the substrate;
forming a protective layer with a second via on the dielectric layer, wherein the first via is communicated with the second via, and a vertical projection of the second via towards the substrate is within a vertical projection of the first via towards the substrate; and wherein
the groove is formed between the substrate and the protective layer.
